(19) United States
(12) Patent Application Publication
(10) Pub. No.: US 2025/0336652 A1
(43) Pub. Date: Oct. 30, 2025

(54) SUBSTRATE PROCESSING SYSTEM WITH A POSITIVELY-BIASED SUBSTRATE AND A METHOD THEREOF

(71) Applicant: ASM IP Holding B.V., Almere (NL)

(72) Inventors: DaeYoun Kim, Seo-gu (KR); Ikjin Choi, Hwasung-si (KR)

(21) Appl. No.: 19/188,381

(22) Filed: Apr. 24, 2025

Related U.S. Application Data
(60) Provisional application No. 63/639,833, filed on Apr. 29, 2024.

(51) Int. Cl. H01J 37/32

(52) U.S. Cl. CPC H01J 37/32697; H01J 2237/0203; H01J 2237/24564

(57) ABSTRACT

A method to apply positively biased DC voltage to a substrate to reduce ion damage during substrate processing and a substrate processing system using the method is presented. For reducing ion damage from the ion bombardment, a substrate processing system may comprise a reaction chamber comprising a susceptor and a substrate process space, wherein the susceptor comprises a heater; and a direct current (DC) bias unit comprising a DC supply configured to generate a triangular-pulsed DC voltage signal and a switch disposed between the DC supply and the susceptor, the switch being configured to open or close a line from the DC supply to the susceptor, wherein the triangular-pulsed DC voltage signal has a first crest and a first frequency.

### CROSS-REFERENCE TO RELATED APPLICATIONS

This application claims priority to U.S. Provisional Patent Application Ser. No. 63/639,833 filed Apr. 29, 2024 titled SUBSTRATE PROCESSING SYSTEM WITH A POSITIVELY-BIASED SUBSTRATE AND A METHOD THEREOF, the disclosure of which is hereby incorporated by reference in its entirety.

### FIELD OF INVENTION

The present disclosure relates to a substrate processing system, more particularly to a substrate processing system in which the substrate susceptor and the substrate is positively biased with DC (direct current) voltage signal. The positive biased substrate (and the susceptor) may reflect and/or deflect the high energy ion bombardment to prevent any ion damage that may be inflicted on the surface of the substrate.

### BACKGROUND OF THE DISCLOSURE

In some CCP (capacitively coupled plasma) semiconductor processing applications, substrates may be damaged from the high energy ions and the same problem may arise in systems using ICP (inductively coupled plasma).

Ion filters may be used to reduce ion damage. But ion filters may reduce not only the ions but also radicals, which are needed in processing the substrates.

Pulsed positive DC bias may be used to reduce ion energy but normal pulsed DC bias may need polarity switching. During this polarity switching, negative voltage may make ions to have higher energy and it may increase the ion damage on the substrates.

Therefore, to overcome the shortcomings described above, the present disclosure presents a method to apply positively biased DC voltage to a substrate and a substrate processing system with the same capabilities to reduce damages from the ions.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a substrate processing system using plasma, comprising: a reaction chamber comprising a susceptor with a heater and a substrate process space; and a direct current (DC) bias unit comprising: a DC supply configured to generate a triangular-pulsed DC voltage signal; and a switch disposed between the DC supply and the susceptor, the switch being configured to open or close a line from the DC supply to the susceptor, wherein the triangular-pulsed DC voltage signal has a first crest and a first frequency.

In at least one aspect, the system further comprises a measuring unit disposed between the switch and the susceptor and configured to measure voltage and current of the line and further configured to measure a capacitance of the heater in the susceptor; and a controller disposed between the measuring unit and the DC supply and connected to the switch, the controller configured to monitor the measured voltage, current and the capacitance and further configured to control the DC supply to change the DC voltage signal's first crest and/or first frequency into a second crest and/or a second frequency.

In at least one aspect, the controller further configured to calculate a biased positive voltage on the substrate with an equation (eq1) below,

$$V ( substrate ) = V ( bias ) + \int \frac{I ( plasma )}{C ( heater )} dt + V 0 , \qquad eq1 )$$

(V (substrate): a biased positive voltage induced on the substrate, V (bias): a voltage generated from the DC supply, I (plasma): a current flowing from a plasma to the heater, C (heater): a capacitance of the heater, V 0: an initial voltage of the substrate).

In at least one aspect, the controller is further configured to switch off the pulsed DC voltage signal at the signal's crest until a next cycle of the pulsed DC voltage signal starts.

In at least one aspect, the controller is further configured to monitor whether the V (substrate) reaches above a first threshold voltage or below a second threshold voltage.

In at least one aspect, the controller is further configured to control the DC supply to increase an amplitude of the DC voltage signal if the V (substrate) reaches below the second threshold voltage and to decrease the amplitude of the DC voltage signal if the V (substrate) reaches above the first threshold voltage.

In at least one aspect, the biased positive voltage on the substrate is strong enough to reflect ions from the plasma so that the substrate is not damaged from an ion bombardment.

In accordance with another embodiment there may be provided, a method to apply positively biased DC voltage to a substrate to reduce ion damage during substrate processing, the method comprising: generating a triangular-pulsed DC voltage signal; applying the generated triangular-pulsed DC voltage signal to a substrate support to maintain a positive DC bias on a surface of the substrate; and switching off the DC signal periodically when the DC voltage signal reaches its crest in each cycle, wherein the generated triangular-pulsed DC voltage signal has a first crest and a first frequency.

In at least one aspect, the method further comprising measuring and calculating parameters.

In at least one aspect, the parameters include a biased positive voltage induced on the substrate [V (substrate)], a voltage generated from a DC supply [V (bias)], a current flowing from a plasma to a heater [I (plasma)], a capacitance value of the heater [C (heater)], and an initial voltage of the substrate [V 0].

In at least one aspect, a biased positive voltage on the substrate is calculated with an equation (eq2) below,

$$V ( substrate ) = V ( bias ) + \int \frac{I ( plasma )}{C ( heater )} d t + V 0 . \qquad eq2 )$$

In at least one aspect, the method further comprises determining whether the calculated voltage, V (substrate), reaches above a first threshold voltage or below a second threshold voltage; and increasing an amplitude of the DC voltage signal if the V (substrate) reaches below the second threshold voltage and decreasing the amplitude of the DC voltage signal if the V (substrate) reaches above the first threshold voltage.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of a substrate processing system according to an embodiment of the present disclosure.

FIG. 2 illustrates (a) the voltage signal supplied by a DC supply and the change (increase) of its amplitude with an amount of ‘A’ according to an embodiment of the present disclosure and (b) the positively biased substrate (or susceptor) when the bias reaches below V 2 (a second threshold) at time t2 according to an embodiment of the present disclosure.

FIG. 3 illustrates (a) the voltage signal supplied by a DC supply and the change (decrease) of its amplitude with an amount of ‘B’ according to an embodiment of the present disclosure and (b) the positively biased substrate (or susceptor) when the bias reaches above V 1 (a first threshold) at time t2 according to an embodiment of the present disclosure.

FIG. 4 illustrates (a) bias change due to a voltage signal from a DC supply without switching off and (b) bias change due to a voltage signal from a DC supply with switching off according to an embodiment of the present disclosure.

FIG. 5 illustrates (a) a diagram describing radicals and ions bombarding on the substrate without any positive bias on the substrate and (b) a diagram describing radicals and ions bombarding on the substrate, but ions are reflected and/or deflected from the positive bias while radicals are not affected according to an embodiment of the present disclosure.

FIG. 6 illustrates a flowchart describing the flow of positive bias method according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. M any alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

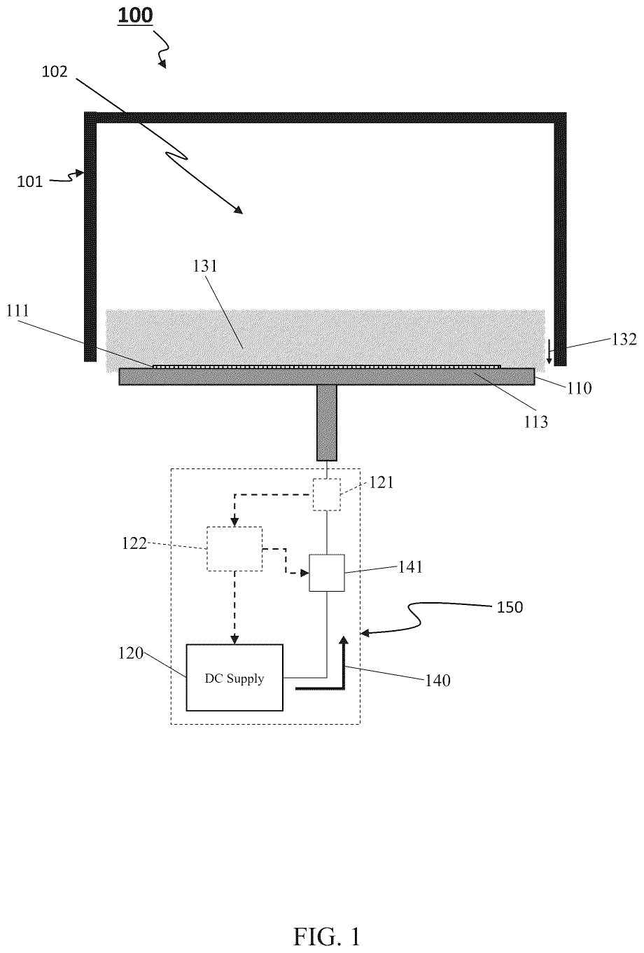

FIG. 1 illustrates an overview of a substrate processing system according to an embodiment of the present disclosure.

The substrate processing system 100 may comprise a reaction chamber 101 with a substrate process space 102 and a susceptor 110 with a heater 113. A substrate 111 may be placed on the susceptor 110. Below the susceptor 110, a direct current (DC) bias unit 150 may be disposed.

The DC bias unit 150 may comprise a DC supply 120, which may generate and supply a triangular-pulsed DC voltage signal (it will be explained later) to the susceptor 110. The DC bias unit 150 also may comprise a switch 141 disposed between the DC supply 120 and the susceptor 110, a measuring unit 121 disposed between the switch 141 and the susceptor 110, and a controller 122 disposed between the measuring unit 121 and the DC supply 120. The controller 122 may be connected to the switch 141.

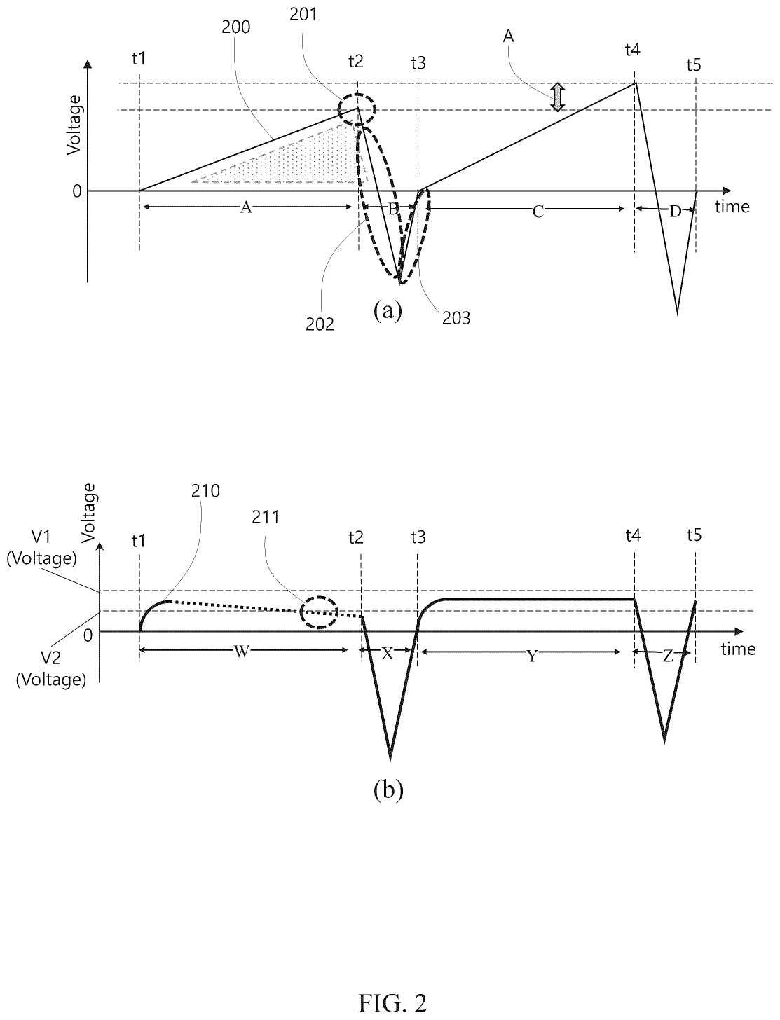

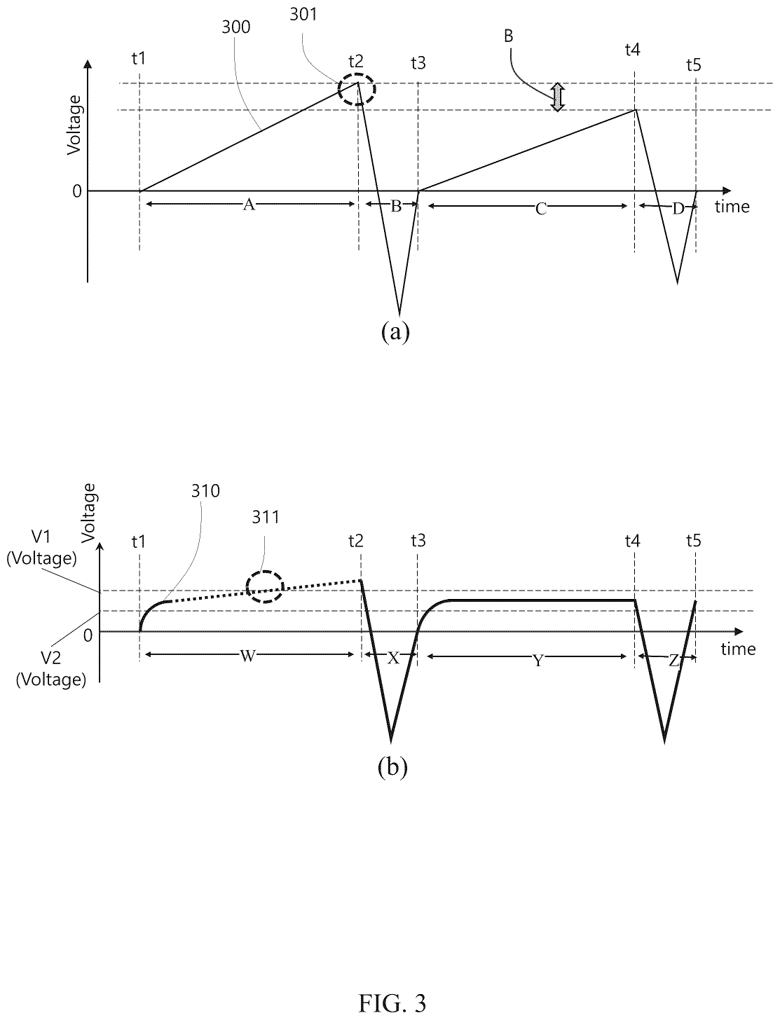

The DC supply 120 may generate a triangular-pulsed DC voltage signal, which may be shown in FIG. 2 (a) (200) and FIG. 3 (a) (300). In FIG. 2 (a), the resemblance of signal 200 and the triangle 202 may explain why the pulse generated in the DC supply 120 may be called a ‘triangular-pulse’.

Among the radicals and ions generated in the plasma environment, ions may need to be removed since the ion bombardment would cause ion damage on the substrate surface. The ions are charged with positive charge therefore if the substrate and susceptor on which the substrate may be placed may be charged with positive charge, then the ions may be reflected and/or deflected from the substrate so the ion damage may be reduced.

The measuring unit 121 may be disposed between the switch 141 and the susceptor 110. The measuring unit 121 may measure parameters such as voltages and currents and capacitances. The voltage from the DC supply 120, denoted as V (bias), the current 132 flowing from a plasma in the substrate process space 102 into the susceptor area, denoted as I (plasma), and a capacitance formed in the heater 113, denoted as C (heater), may be measured.

The switch 141 may switch off (open circuit) the signal 140 from the DC supply 120 and may switch on (close circuit) the signal 140 to the susceptor 110 periodically. In FIG. 2 (a), the triangular-pulsed DC voltage signal 200 may have recurring cycles, each cycle may has increasing phase (A phase and C phase) and decreasing & restoring phase (B phase and D phase). When the signal 200 reaches at its crest at point 201, the switch 141 may switch off (circuit open) at time (t2) until time (t3) during the decreasing phase 202 & restoring phase 203 so that the negative voltage in phases 202, 203 may not affect the voltage in the substrate like the negative drop shown in the ‘X phase’ in FIG. 2 (b). When the signal 200 restarts at time t3, the switch 141 may switch on (close circuit) so that the generated signal 200 may flow into the susceptor 110.

The controller 122 may monitor and control the units 120, 141, 121. The positive bias on the substrate 111 (and/or the susceptor 110 & heater 113), denoted as V (substrate), may be calculated from the measured parameters with an equation (EQ) below.

$$V ( substrate ) = V ( bias ) + \int \frac{I ( plasma )}{C ( heater )} dt + V 0 , \qquad ( EQ )$$

(wherein V 0 may be the initial voltage of the substrate).

FIG. 2 (b) illustrates the calculated bias voltage on the substrate 131, V (substrate), with no switch off. The voltage 210 may be stabilized and may oscillate but the allowed oscillation gap may be from a second threshold voltage (V 2) to a first threshold voltage (V 1). And when the calculated bias voltage, V (substrate), reaches below V 2 in ‘phase W’ (211), the controller 122 may increase the amplitude of the generated signal in the next cycle starting at time t3. In FIG. 2 (a), the increased amount of amplitude may be denoted as ‘A’ and this increase may be enough to maintain the calculated bias voltage, V (substrate), as flat as shown in ‘phase Y’ in FIG. 2 (b).

When DC supply 120 may generate and supply a triangular-pulsed DC voltage signal 140, the substrate 111 (and/or the susceptor 110 & heater 113) may be positively biased 131 but the bias may be discharged gradually down to zero with no continuous supply of the signal 140 and for substrate uniformity and protection from the ion damages, the positive bias 131 may need to be maintained uniformly throughout the processing period by supplying gradually increasing voltage signal like ‘triangular-pulse’ 200. However, the signal 200 cannot be increased indefinitely so the decreasing phase 202 and restoring phase 203 may exist and these phases are switched off (disconnected or open) as explained above.

FIG. 3 (b) illustrates the calculated bias voltage on the substrate 131, V (substrate), with no switch off. The voltage 310 may be stabilized and may oscillate but the allowed oscillation gap may be from a second threshold voltage (V 2) to a first threshold voltage (V 1). And when the calculated bias voltage, V (substrate), reaches above V 1 in ‘phase W’ (311), the controller 122 may decrease the amplitude of the generated signal in the next cycle starting at time t3. In FIG. 3 (a), the decreased amount of amplitude may be denoted as ‘B’ and this decrease may be enough to maintain the calculated bias voltage, V (substrate), as flat as shown in ‘phase Y’ in FIG. 3 (b).

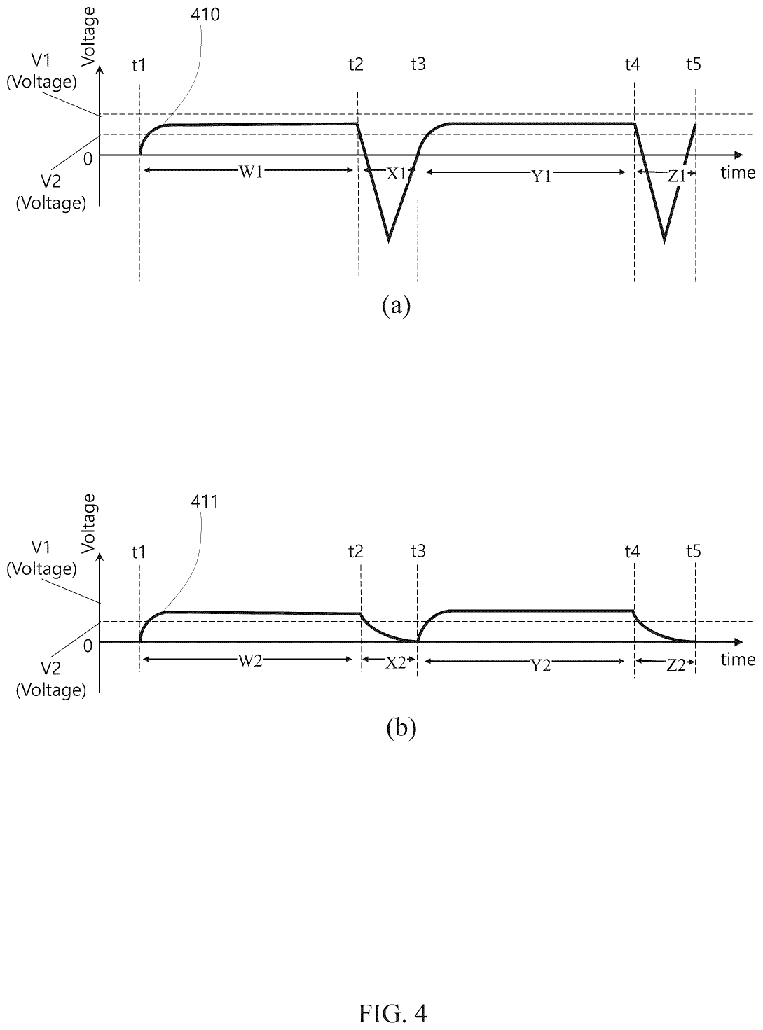

FIG. 4 (a), with no switch off, the calculated bias voltage, V (substrate) 410, may drop so rapidly below zero in phases X1 and Z1. With negative bias on the substrate, the positive ions would get higher energy and would inflict heavier damages on the substrate.

To avoid this ill effect, the controller 122 may be configured to switch off the switch 141 when the generated triangular-pulse signal 200, 300 reaches its crest (201, 301) at time t2 (In FIG. 2 (a) and FIG. 3 (a)). By the switch off, the calculated signal would decrease toward zero gradually (for example, exponentially) in phases X2 and Z2.

Compared to the no switch off case, the switch off case of FIG. 4 (b)'s calculated bias voltage on the substrate, V (substrate) during phases X2 and Z2 would remain above zero and flatter than no switch off case in FIG. 4 (a)'s phases X1 and Z1. This means the protection effect from positive bias may be maintained during the whole cycle and it remains flatter so that the uniformity may also be increased.

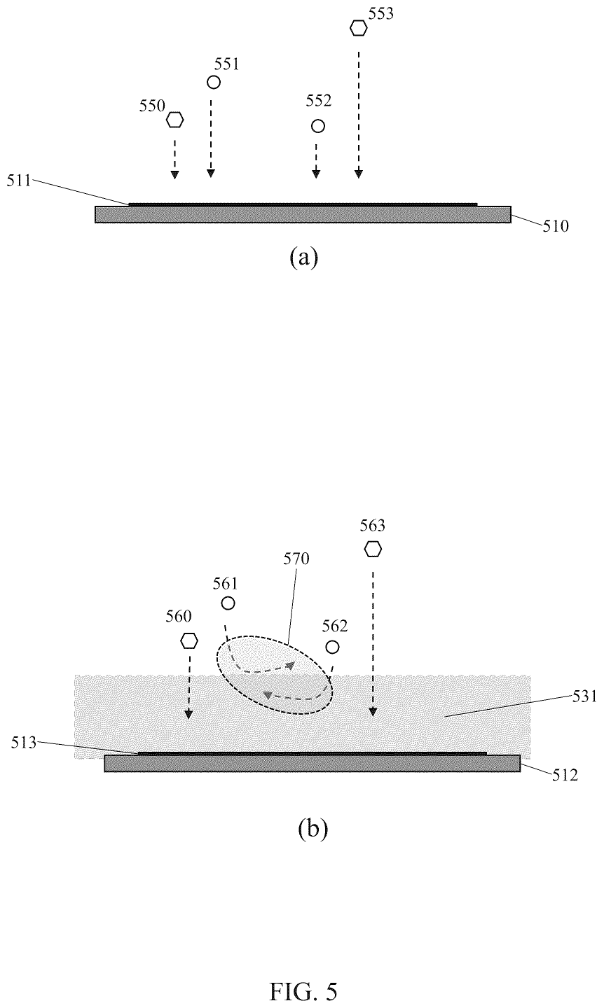

FIG. 5 (a) illustrates a diagram describing radicals 550, 553 and ions 551, 552 bombarding on the substrate 511 placed on the susceptor 510 without any positive bias on the substrate 511. In this case, the ions 551, 552 may inflict ion damage on the substrate 511.

FIG. 5 (b) illustrates a diagram describing radicals 560, 563 and ions 561, 562 bombarding on the substrate 513 placed on the susceptor 512, but ions 561, 562 may be reflected and/or deflected (570) from the positive bias 531 while radicals 560, 563 may not be affected.

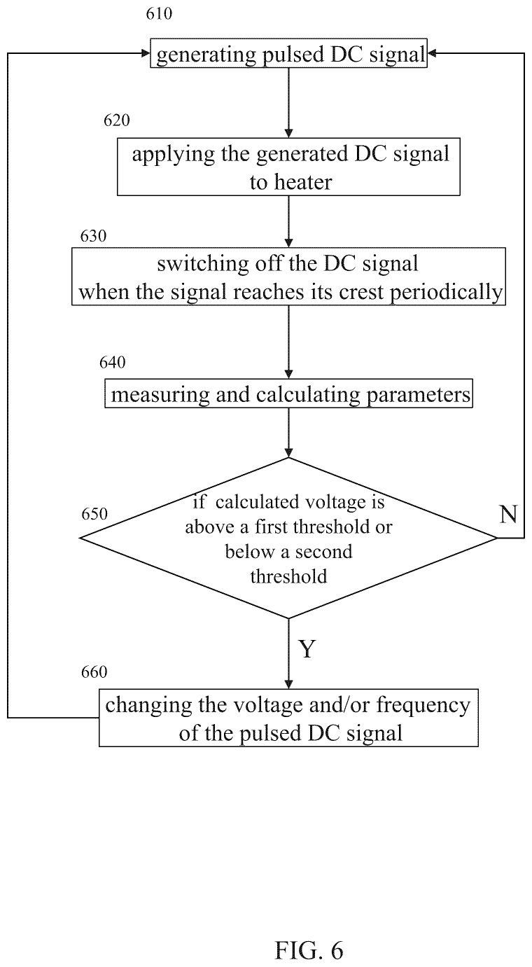

FIG. 6 illustrates a flowchart describing the flow of positive bias method according to an embodiment of the present disclosure.

In step 610 of the method, the DC supply 120 may generate triangular-pulsed DC voltage signal (200, 300) and the generated signal may be applied to the heater in step 620.

And in step 630, the switch 141 may switch off so that the generated signal may not flow into the heater when the signal reaches its crest periodically.

When necessary, the parameters such as the voltage from the DC supply 120, denoted as V (bias), the current 132 flowing from a plasma in the substrate process space 102 into the susceptor area, denoted as I (plasma), and a capacitance formed in the heater 113, denoted as C (heater), may be measured and the bias voltage on the substrate, denoted as V (substrate), may be measured and calculated in step 640 by the controller and the measuring unit.

The bias voltage on the substrate, V (substrate), may be calculated with an equation (EQ) disclosed above.

Then in step 650, the controller may determine the calculated V (substrate) reaches above a first threshold voltage or reaches below a second threshold voltage and the controller may change the amplitude (the height of the signal's crest) of the next restarting cycle of the triangular-pulsed DC voltage signal in step 660. M ore specifically, the controller may increase the amplitude of the triangular-pulsed DC voltage signal if the V (substrate) reaches below the second threshold voltage and decrease the amplitude of the triangular-pulsed DC voltage signal if the V (substrate) reaches above the first threshold voltage.

The above-described arrangements of apparatus and method are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A substrate processing system using plasma, comprising:
a reaction chamber comprising a susceptor and a substrate process space, wherein the susceptor comprises a heater; and
a direct current (DC) bias unit comprising:
a DC supply configured to generate a triangular-pulsed DC voltage signal; and
a switch disposed between the DC supply and the susceptor, the switch being configured to open or close a line from the DC supply to the susceptor,
wherein the triangular-pulsed DC voltage signal has a first crest and a first frequency.

2. The system according to the claim 1, further comprising:
a measuring unit disposed between the switch and the susceptor, wherein the measuring unit is configured to measure a voltage and a current of the line and further configured to measure a capacitance of the heater in the susceptor; and
a controller disposed between the measuring unit and the DC supply and connected to the switch, the controller configured to monitor the voltage, the current, and the capacitance and further configured to control the DC supply to change the DC voltage signal's first crest and/or first frequency into a second crest and/or a second frequency.

3. The system according to the claim 2, wherein the controller is further configured to calculate a biased positive voltage on the substrate with an equation (eq1) below,
$$V ( substrate ) = V ( bias ) + \int \frac{I ( plasma )}{C ( heater )} dt + V 0 , \qquad eq1 )$$
(V (substrate): a biased positive voltage induced on the substrate,
V (bias): a voltage generated from the DC supply,
I (plasma): a current flowing from a plasma to the heater,
C (heater): a capacitance of the heater,
V0: an initial voltage of the substrate).

4. The system according to the claim 2, wherein the controller is further configured to switch off the pulsed DC voltage signal at the signal's crest until a next cycle of the pulsed DC voltage signal starts.

5. The system according to the claim 3, wherein the controller is further configured to monitor whether the V (substrate) reaches above a first threshold voltage or below a second threshold voltage.

6. The system according to the claim 5, wherein the controller is further configured to control the DC supply to increase an amplitude of the DC voltage signal if the V (substrate) reaches below the second threshold voltage and to decrease the amplitude of the DC voltage signal if the V (substrate) reaches above the first threshold voltage.

7. The system according to the claim 3, wherein the biased positive voltage on the substrate is strong enough to reflect ions from the plasma so that the substrate is not damaged from an ion bombardment.

8. A method to apply positively biased DC voltage to a substrate to reduce ion damage during substrate processing, the method comprising:
generating a triangular-pulsed DC voltage signal;
applying the generated triangular-pulsed DC voltage signal to a substrate support to maintain a positive DC bias on a surface of the substrate; and
switching off the DC signal periodically when the DC voltage signal reaches its crest in each cycle;
wherein the generated triangular-pulsed DC voltage signal has a first crest and a first frequency.

9. The method according to the claim 8, further comprising:
measuring and calculating a plurality of parameters.

10. The method according to the claim 9, wherein the plurality of parameters comprises a biased positive voltage induced on the substrate [V (substrate)], a voltage generated from a DC supply [V (bias)], a current flowing from a plasma to a heater [I (plasma)], a capacitance value of the heater [C (heater)], and an initial voltage of the substrate [V 0].

11. The method according to the claim 10, wherein a biased positive voltage on the substrate is calculated with an equation (eq2) below,
$$V ( substrate ) = V ( bias ) + \int \frac{I ( plasma )}{C ( heater )} d t + V 0 . \qquad eq2 )$$

12. The method according to the claim 11, further comprising:
determining whether the calculated voltage, V (substrate), reaches above a first threshold voltage or below a second threshold voltage; and
increasing an amplitude of the DC voltage signal if the V (substrate) reaches below the second threshold voltage and decreasing the amplitude of the DC voltage signal if the V (substrate) reaches above the first threshold voltage.
